(19) United States
(12) Patent Application Publication
(10) Pub. No.: US 2008/0087907 A1
(43) Pub. Date: Apr. 17, 2008

(54) Light emitting diode package

(75) Inventors: Hee Seok Park, Suwon (KR); Gil Han Park, Sungnam (KR); Sang Duk Yoo, Sungnam (KR); Ki Tae Park, Suwon (KR); Myoung Sik Jung, Seoul (KR); Kyeong Ik Min, Seoul (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO. LTD

(21) Appl. No.: 11/898,542

(22) Filed: Sep. 13, 2007

(30) Foreign Application Priority Data
Oct. 11, 2006 (KR) 10-2006-98964

(51) Int. Cl. H01L 33/00

(52) U.S. Cl. 257/98; 257/E33.001

(57) ABSTRACT

A light emitting diode package including: a package substrate having a mounting area and first and second wiring structures partially exposed in the mounting area; a light emitting diode having first and second electrodes, the light emitting diode mounted on the mounting area of the package substrate to allow the first and second electrodes to be connected to first and second bonding pads, respectively; a transparent cover mounted above the mounting area of the package substrate to hermetically seal a mounting space in which the light emitting diode is mounted; and a transparent electric insulation fluid filled in the mounting space of the hermetically sealed light emitting diode and having a refractive index smaller than a refractive index of a material forming the light emitting diode.

### CLAIM OF PRIORITY

This application claims the benefit of Korean Patent Application No. 2006-0098964 filed on Oct. 11, 2006, in the Korean Intellectual Property Office, the disclosure of which is incorporated herein by reference.

### BACKGROUND OF THE INVENTION

1. Field of the Invention

The present invention relates to a nitride semiconductor light emitting device, and more particularly, to a nitride semiconductor light emitting device with improved light extraction efficiency and to a method of manufacturing the same.

2. Description of the Related Art

In general, light efficiency of a nitride semiconductor light emitting device is determined by internal quantum efficiency and light extraction efficiency, also called external quantum efficiency. In particular, the light extraction efficiency of the light emitting device is determined by optical factors, i.e., at least one of refractive indices of structures and flatness of interfaces of the light emitting device.

In terms of light extraction efficiency, a nitride light emitting device has fundamental limitations. That is, since the semiconductor layer forming the semiconductor light emitting device has a greater refractive index than a refractive index of one of the atmosphere and a substrate, a critical angle determining a range of an incident angle at which light is emitted out of the device is small.

Therefore, most portion of light generated from an active layer of the semiconductor light emitting device is totally internally reflected to propagate in unintended directions or to be lost, resulting in low light extraction efficiency.

More specifically, in a nitride-based semiconductor light emitting device, since GaN has a refractive index of about 2.4, the light generated from the active layer is internally totally reflected at an incident angle greater than a critical angle of 23.6° at an interface of GaN and the atmosphere. Thus, the light is totally internally reflected to propagate in lateral directions and is eventually lost or emitted in undesired directions, thereby resulting in light extraction efficiency of only about 6%. Similarly, since a sapphire substrate has a refractive index of 1.78, the light extraction efficiency is low at an interface of the sapphire substrate and the atmosphere.

To solve this problem, conventionally, a resin layer having a lower refractive index than the nitride semiconductor is formed on a surface of or adjacent to the nitride semiconductor light emitting device, in manufacturing a package structure.

However, in a case of a light emitting diode having one of an uneven surface structure or a hexagonal pyramid-shaped structure recently in development, air bubbles are generated in the resin layer due to the uneven or angled surface, which in turn adversely affects light extraction.

### SUMMARY OF THE INVENTION

An aspect of the present invention provides a light emitting diode package employing a different medium for adjusting a refractive index to improve light extraction efficiency, thereby usefully applied to light emitting diodes having various surface structures and uneven surface structures.

According to an aspect of the invention, there is provided a light emitting diode package including: a package substrate having a mounting area and first and second wiring structures partially exposed in the mounting area; a light emitting diode having first and second electrodes, the light emitting diode mounted on the mounting area of the package substrate to allow the first and second electrodes to be connected to first and second bonding pads, respectively; a transparent cover mounted above the mounting area of the package substrate to hermetically seal a mounting space in which the light emitting diode is mounted; and a transparent electric insulation fluid filled in the mounting space of the hermetically sealed light emitting diode and having a refractive index smaller than a refractive index of a material forming the light emitting diode.

The transparent electric insulation fluid may be a silicon oil.

The transparent cover may being lens structure capable of collecting light emitted from the light emitting diode. In this case, the transparent cover may be a fluorescent material capable of exciting light emitted from the light emitting diode to emit light of a different wavelength.

The package substrate may have a recessed portion provided as the mounting area. In order to improve luminance, an inner side wall surrounding the recessed portion of the package substrate may be an upwardly inclined reflecting surface.

The light emitting diode may have at least one hexagonal pyramid structure, and the light emitting diode may have an uneven structure formed on at least one surface thereof to improve light extraction efficiency.

### BRIEF DESCRIPTION OF THE DRAWINGS

The above and other aspects, features and other advantages of the present invention will be more clearly understood from the following detailed description taken in conjunction with the accompanying drawings, in which:

FIGS. 1A and 1B are a perspective view and a side cross-sectional view illustrating a light emitting diode package according to an exemplary embodiment of the present invention, respectively;

FIGS. 2A and 2B are side cross-sectional views illustrating a light emitting diode package having a light emitting diode with at least one hexagonal pyramid surface structure capable of being employed to an exemplary embodiment of the present invention; and

FIG. 3 is a side cross-sectional view illustrating a light emitting diode package according to an exemplary embodiment of the present invention.

### DETAILED DESCRIPTION OF THE PREFERRED EMBODIMENT

Exemplary embodiments of the present invention will now be described in detail with reference to the accompanying drawings.

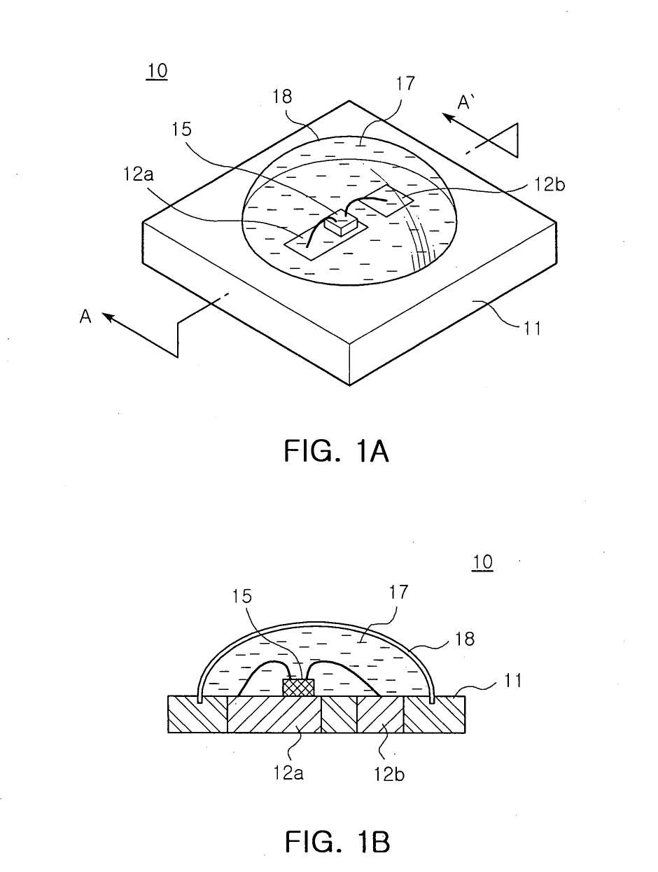

FIGS. 1A and 1B are a perspective view and a side cross-sectional view illustrating a light emitting diode package according to an exemplary embodiment of the present invention.

As shown in FIGS. 1A and 1B, the light emitting diode package 10 includes a package substrate 11 with a light emitting diode 15 mounted on an upper surface thereof.

The package substrate 11 has first and second wiring structures 12a and 12b formed of conductive vias, respectively, in the substrate 11. The light emitting diode 15 mounted on the package substrate 11 may be connected to the first and second wiring structures 12a and 12b by a known method of connection such as wire bonding.

The light emitting diode package 10 includes a transparent cover 18 mounted above a mounting area of the package substrate. The transparent cover 18 may be a lens as shown and has a structure sealing a space surrounding the area on which the light emitting diode 15 is mounted.

As described above, the transparent cover 18 provides the sealed space in which the light emitting diode 15 is disposed. A transparent fluid 17 for adjusting a refractive index is filled in the sealed space formed by the transparent cover 18. The transparent fluid 17 has electric insulating properties so as not to affect the electric connection structure.

In addition, the transparent fluid 17 employed in the present embodiment has a refractive index value between a refractive index value of a material forming the light emitting diode 15 and a refractive index of the atmosphere, thereby increasing an amount of light extracted out of the light emitting diode 15. For example, in a case where the light emitting diode is formed of GaN, since GaN has a refractive index of about 2.4, the transparent fluid 17 is formed of a material having a refractive index lower than 2.4.

The transparent fluid 17 satisfying the conditions for electric insulating properties and adjustment of the refractive index may be, but not limited to, a silicon-based oil.

Having fluidity, the transparent fluid 17 used for adjusting the refractive index may form an eddy, effectively radiating the heat generated from the surface of the light emitting diode. Also, the transparent fluid 15 maintains a close contact with the surface of the light emitting diode regardless of the shape and the surface structure of the light emitting diode to adjust the refractive index, thereby effectively improving the light extraction efficiency.

In particular, the transparent fluid for adjusting the refractive index may be usefully employed to one of a hexagonal pyramid-shaped light emitting diode and a light emitting diode having an uneven surface structure to thereby further improve light extraction efficiency.

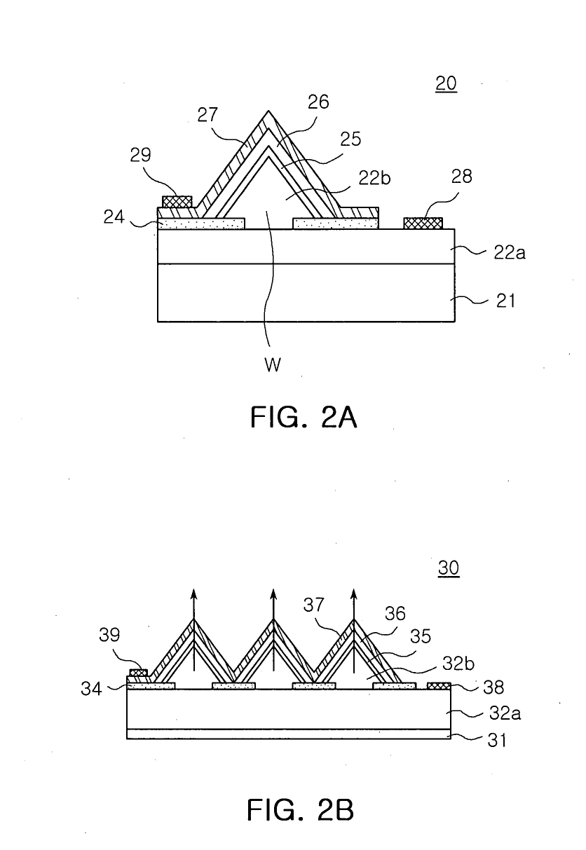

FIGS. 2A and 2B are side cross-sectional views illustrating examples of light emitting diodes having at least one hexagonal pyramid structure, the light emitting diodes capable of being usefully employed in the present invention.

As shown in FIG. 2A, a light emitting diode 20 having a single hexagonal pyramid structure includes a sapphire substrate 21 and a first conductivity type lower nitride semiconductor layer 22a formed on the sapphire substrate 21.

Also, a dielectric layer 24 having a window area W is formed on the first conductivity type lower nitride layer 22a. Lateral growth using the dielectric layer 24 is applied to grow a first conductivity type upper nitride layer 22b, an active layer 25 and a second conductivity type nitride layer 26 in the window area W. Thereby, the nitride layers 22b, 25 and 26 form a hexagonal pyramid light emitting structure in the window area W.

In addition, a transparent conductive film 27 and a second electrode 29 are formed on the second conductivity type nitride layer 26 of the hexagonal pyramid light emitting structure, and a first electrode 28 is formed on a portion of the first conductivity type lower nitride layer 22a exposed by etching a portion of the dielectric layer 24.

In such a hexagonal pyramid-shaped structure, even if a vacuuming process performed during a process of applying and curing a resin may not completely prevent generation of air bubbles, which may adversely affect light extraction. However, according to the present invention, the transparent fluid having electric insulating properties is employed to provide a condition of a lower refractive index than that of the material forming the light emitting diode, thereby effectively improving light extraction efficiency.

FIG. 2B illustrates a more complicated structure of a hexagonal pyramid light emitting structure array. Similar to the embodiment shown in FIG. 2A, a hexagonal pyramid light emitting device array 30 includes a substrate 31 and a first conductivity type lower nitride semiconductor layer 32 formed on the substrate 31.

A dielectric layer 34 with a plurality of window areas formed therethrough is formed on the first conductivity type lower nitride layer 32. A first conductivity type upper nitride layer 32b, an active layer 35 and a second conductivity type nitride layer 36 are sequentially grown on areas on the first conductivity type lower nitride layer 32a exposed by the respective window areas, thereby providing a plurality of hexagonal pyramid light emitting structures.

In addition, a first electrode 38 is formed on an upper surface of the first conductivity type lower nitride semiconductor layer 32a. A light-transmitting conductive layer 37 is formed on the second conductivity type nitride semiconductor layer 36, and a second electrode 39 is formed on an upper surface of the light transmitting conductive layer 37.

As described above, the light emitting diode structure having the plurality of pyramid-shaped structures has a severely irregular surface shape. In this case, even if a curable liquid resin is used to form a layer for adjusting the refractive index, drawbacks such as light scattering due to air bubbles and the like may be more severe.

However, when a transparent fluid such as a silicon oil is employed according to the present invention, an entirely dense structure for adjusting the refractive index may be provided and the heat generated from the light emitting device may be effectively radiated through eddy effects of the fluid.

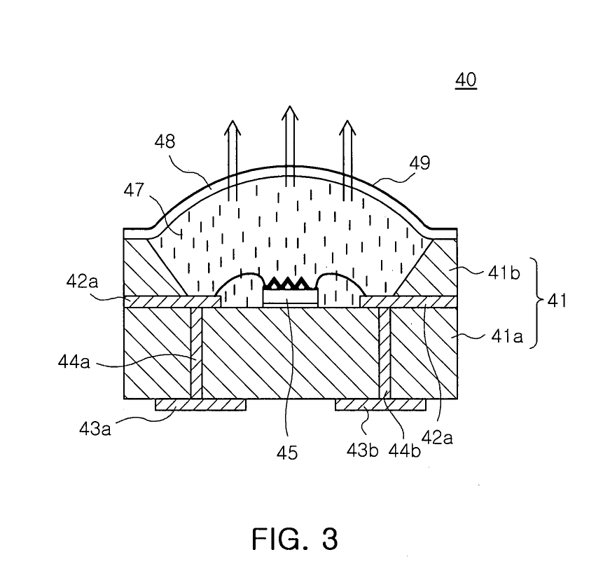

FIG. 3 is a side cross-sectional view illustrating a package employing the light emitting diode shown in FIG. 2B.

Referring to FIG. 3, the light emitting diode package 40 includes a package substrate 41 including a lower substrate 41a having a wiring structure and an upper substrate 41b having a cavity formed therein. For example, each of the upper and lower substrates 41b and 41a may be a silicon substrate.

According to the present embodiment, the wiring structure formed on the lower substrate 41a may include lead frames 42a and 42b formed on an upper surface thereof, bonding pads 43a and 43b formed on a lower surface thereof, and conductive vias 44a and 44b connecting the lead frames 42a and 42b with the bonding pads 43a and 43b, respectively. The cavity defining a mounting space is formed in the upper substrate 41b. The sidewall of the cavity is an upwardly inclined surface, which may be utilized as a reflecting surface.

The light emitting device 45 is mounted in the mounting space defined by the cavity and connected to the lead frames 42a and 42b. A transparent cover 48 is mounted above the upper substrate 41b, in a shape covering the cavity structure. The transparent cover 48 may be firmly attached by a known means to hermetically seal the space in which the light emitting diode 45 is mounted. The transparent cover 48 may be in a lens structure having a hemispheric shape as shown in FIG. 3.

In addition, the transparent cover 48 may include a phosphor. The phosphor may be provided in a powder form included in the transparent cover, but also a phosphor film 49 may be formed on an outer surface of the transparent cover as in this embodiment. Of course, the phosphor film 49 may be also formed on an inner surface of the transparent cover 48 if necessary.

A transparent fluid 47 having electric insulating properties is filled in the space hermetically sealed by the transparent cover 48. In order to increase light extraction efficiency, the transparent fluid 47 may have a refractive index value between a refractive index value of the material forming the light emitting diode 45 and a refractive index value of the external atmosphere. Therefore, the amount of light extracted out of the light emitting diode 45 is increased. Although not limiting, a silicon-based oil may be used for the transparent fluid 17 satisfying the condition for the electric insulating properties and adjustment of the refractive index.

Thereby, even if the hexagonal pyramid shaped light emitting diode has a severely irregular surface, the medium for adjusting the refractive index employs a fluid having a large fluidity like liquid, which adjusts the refractive index while maintaining a close contact with the surface of the light emitting diode, thereby effectively improving light extraction property.

According to the present invention as set forth above, a fluid having electric insulating properties and high fluidity is employed for a medium for adjusting a refractive index, thereby effectively improving light extraction efficiency of a light emitting device having a light emitting diode with various surface structures and uneven surface structures.

While the present invention has been shown and described in connection with the exemplary embodiments, it will be apparent to those skilled in the art that modifications and variations may be made without departing from the spirit and scope of the invention as defined by the appended claims.

What is claimed is:

1. A light emitting diode package comprising:
a package substrate having a mounting area and first and second wiring structures partially exposed in the mounting area;
a light emitting diode having first and second electrodes, the light emitting diode mounted on the mounting area of the package substrate to allow the first and second electrodes to be connected to the first and second wiring structures, respectively;
a transparent cover mounted above the mounting area of the package substrate to hermetically seal a mounting space in which the light emitting diode is mounted; and
a transparent electric insulation fluid filled in the mounting space of the hermetically sealed light emitting diode and having a refractive index smaller than a refractive index of a material forming the light emitting diode.

2. The light emitting diode package of claim 1, wherein the transparent electric insulation fluid is a silicon oil.

3. The light emitting diode package of claim 1, wherein the transparent cover is in a lens structure capable of collecting light emitted from the light emitting diode.

4. The light emitting diode package of claim 1, wherein the transparent cover comprises a phosphor capable of exciting light emitted from the light emitting diode to emit light of a different wavelength.

5. The light emitting diode package of claim 2, wherein the transparent cover comprises a phosphor capable of exciting light emitted from the light emitting diode to emit light of a different wavelength.

6. The light emitting diode package of claim 3, wherein the transparent cover comprises a phosphor capable of exciting light emitted from the light emitting diode to emit light of a different wavelength.

7. The light emitting diode package of claim 1, wherein the package substrate has a recessed portion provided as the mounting area.

8. The light emitting diode package of claim 7, wherein an inner side wall surrounding the recessed portion of the package substrate is an upwardly inclined reflecting surface.

9. The light emitting diode package of claim 1, wherein the light emitting diode has at least one hexagonal pyramid structure.

10. The light emitting diode package of claim 1, wherein the light emitting diode has an uneven structure formed on at least one surface thereof to improve light extraction efficiency.
